(19) United States
(12) Patent Application Publication
(10) Pub. No.: US 2016/0085104 A1
(43) Pub. Date: Mar. 24, 2016

(54) MASK, SPACER PRODUCED BY USING THE MASK AND METHOD FOR PRODUCING SPACER USING THE MASK

(71) Applicants: BOE Technology Group Co., Ltd., Beijing (CN); Beijing BOE Display Technology Co., Ltd., Beijing (CN)

(72) Inventor: Hongshu Zhang, Beijing (CN)

(21) Appl. No.: 14/801,985

(22) Filed: Jul. 17, 2015

(30) Foreign Application Priority Data
Sep. 19, 2014 (CN) 201410482872.6

(51) Int. Cl. G02F 1/1339; G03F 1/50; G03F 7/40; G03F 7/20; G03F 7/32; G02B 5/18; G03F 7/16

(52) U.S. Cl. CPC G02F 1/13394; G02B 5/1876; G03F 1/50; G03F 7/16; G03F 7/20; G03F 7/32; G03F 7/40

(57) ABSTRACT

Embodiments of the present invention provide a mask, a spacer produced by the mask and a method for producing a spacer using the mask. They may reduce the bottom size of a cylinder-shaped spacer while keeping the top size of it to meet the design requirements for high resolution TFT-LCD. The mask provided by the embodiments includes a mask substrate on which a light transmission region and a light shielding region are provided, wherein a Fresnel zone plate is arranged in the light transmission region and configured to form a spacer on a glass substrate.

### CROSS-REFERENCE TO RELATED APPLICATION

This application claims the benefit of Chinese Patent Application No. 201410482872.6 filed on Sep. 19, 2014 in the State Intellectual Property Office of China, the whole disclosure of which is incorporated herein by reference.

### BACKGROUND OF THE INVENTION

1. Field of the Invention

The present disclosure relates to the technical field of exposure process in production of a liquid crystal display apparatus, and in particular, relates to a mask, a spacer produced by using the mask and a method for producing spacer using the mask.

2. Description of the Related Art

Currently, a TFT-LCD (thin film transistor-liquid crystal display), as a display apparatus having perfect display effects and low power consumption becomes more and more popular.

The TFT-LCD panel is mainly made of a color filter substrate and an array substrate as well as a liquid crystal layer filled between these two glass substrates (i.e., the color filter substrate and the array substrate), and controls the liquid crystal by voltages to produce points, lines or planes and to form a picture cooperating with the lights on the backside. In order to ensure uniformity and stability of the thickness of the liquid crystal layer, typically, a spacer is provided between the two substrates to space them, in order to form a room for injecting liquid crystal. The spacer may be formed by processes of such as exposing photo resist to light by means of the mask, developing the photo resist and etching it. In an example, the conventional mask is typically provided with an opening to form an exposed area at the opening. The process of forming the spacer by the conventional mask is provided as follows: at first, coating the glass substrate (typically array substrate) with a layer of photo resist for forming the spacer, then, exposing the photo resist to the light by the conventional mask, developing the photo resist so as to form a cylinder-shaped spacer having a small top size and a large bottom size. In this case, as the spacer is a non-display component, it needs to be covered by a black matrix.

As the science and technology develop, the resolution of the TFT-LCD becomes more and more high. In addition, as the black matrix for the high resolution TFT-LCD has a small size and the space for placing the cylinder-shaped spacer is small, it needs to reduce the vertical contact area as small as possible, that is, the cylinder-shaped spacer has a relatively small bottom size.

### SUMMARY OF THE INVENTION

An embodiment of the present invention provides a mask, comprising a mask substrate on which a light transmission region and a light shielding region are provided, wherein a Fresnel zone plate is arranged in the light transmission region and configured to form a spacer on a glass substrate.

An embodiment of the present invention also provides a spacer produced by using a mask, the mask comprising a mask substrate on which a light transmission region and a light shielding region are provided, wherein a Fresnel zone plate is arranged in the light transmission region and configured to form a spacer on a glass substrate.

An embodiment of the present invention also provides a method for producing a spacer using a mask, the mask comprising a mask substrate on which a light transmission region and a light shielding region are provided, wherein a Fresnel zone plate is arranged in the light transmission region and configured to form a spacer on a glass substrate, the method comprising: coating the substrate with a layer of photo resist; and forming the spacer on the substrate by using the mask to expose the layer of photo resist to light, to develop and etch the layer of photo resist in sequence.

### BRIEF DESCRIPTION OF THE DRAWINGS

FIG. 1 is a schematic view showing a mask according to an embodiment of the present invention;

FIG. 2 is a schematic view showing a structure of a Fresnel zone plate in the mask according to an embodiment of the present invention;

FIG. 3 is a view showing a principle of forming a spacer by using a mask according to an embodiment of the present invention;

FIG. 4 is a schematic view showing a mask according to another embodiment of the present invention;

FIG. 5 is a schematic view showing a mask according to a further embodiment of the present invention;

FIG. 6 schematically shows a spacer having a special shape according to an embodiment of the present invention;

FIG. 7 is a flow chart of a method for producing a spacer according to an embodiment of the present invention; and

FIGS. 8a-8b are schematic views showing the structures corresponding to the flows of the method for producing the spacer according to an embodiment of the present invention.

### DETAILED DESCRIPTION OF PREFERRED EMBODIMENTS

Below, the mask according to embodiments of the present disclosure will be described in detail with reference to the attached drawings. It should be noted that the described embodiments are only given out by way of examples, instead of all of embodiments of the present invention.

According to a general concept of the present invention, it provides a mask, comprising a mask substrate on which a light transmission region and a light shielding region are provided, wherein a Fresnel zone plate is arranged in the light transmission region and configured to form a spacer on a glass substrate.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

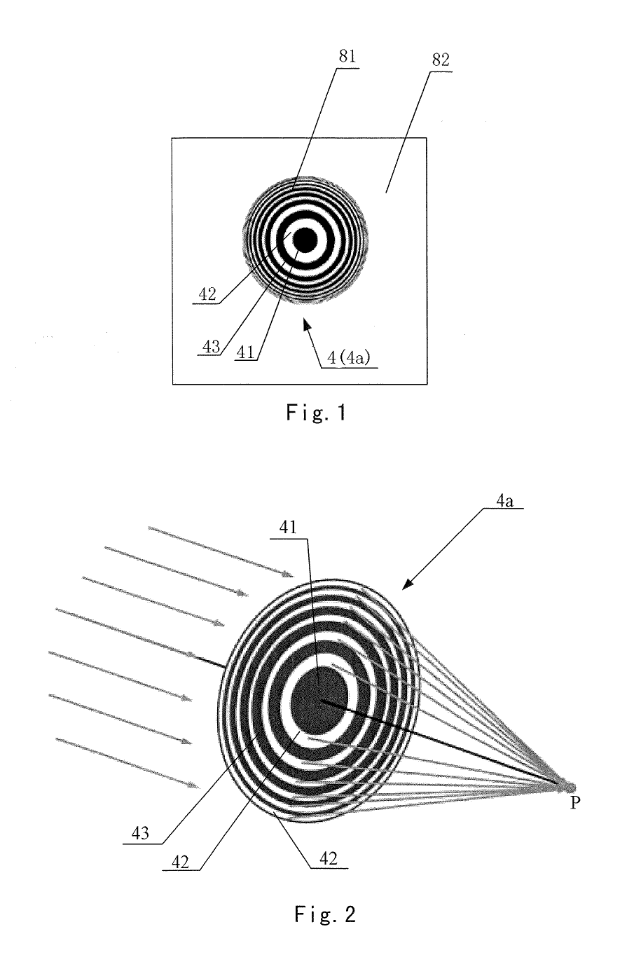

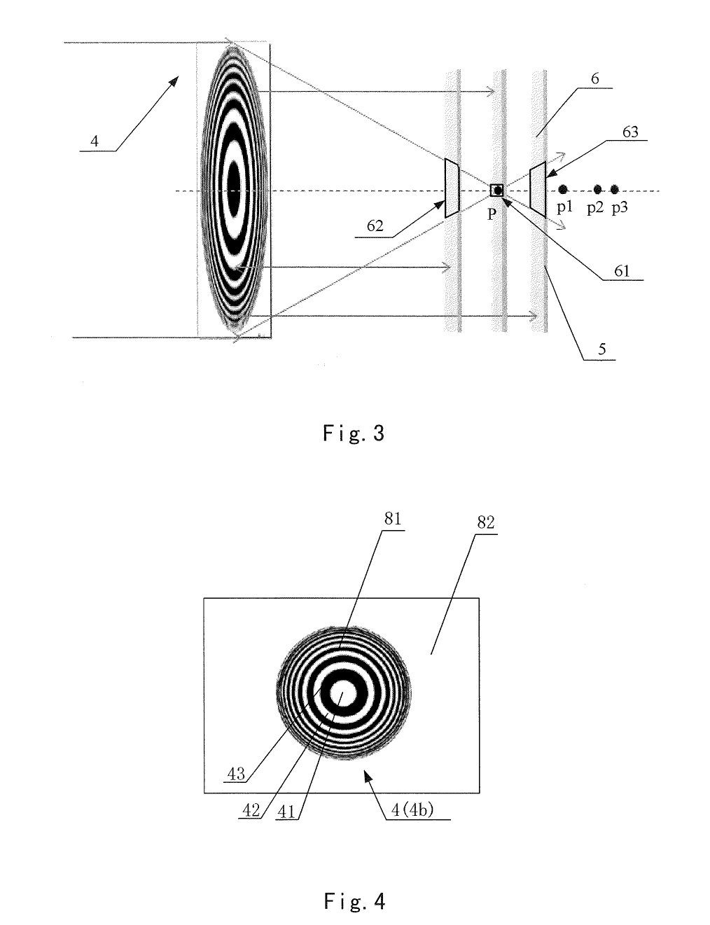

An embodiment of the present invention provides a mask. As illustrated in FIGS. 1 and 3, the mask includes a mask substrate on which a light transmission region 81 and a light shielding region 82 are provided. A Fresnel zone plate 4 (4b) is arranged in the light transmission region 81 and configured to form a spacer on a glass substrate 5, for example a cylinder-shaped spacer 61 and/or an inverse cone-shaped spacer 62 and/or a positive cone-shaped spacer 63.

In the mask provided by the embodiment of the present invention, it includes the mask substrate on which the light transmission region 81 and the light shielding region 82 are provided. And a Fresnel zone plate 4 (4b) is arranged in the light transmission region 81 and configured to form a spacer on a glass substrate 5. In this way, the mask provided with the Fresnel zone plate may produce a huge intensity of light by using the light concentration effect of the Fresnel zone plate. The mask may also be used in the processes of exposing, developing and etching for the photo resist. In addition, by setting the distance between the photo resist and the mask (for example, the photo resist is located at the main focus length of the mask or within the main focus length of the mask), the cylinder-shaped spacer and the inverse cone-shaped spacer may be formed on the glass substrate and the black matrix. In this way, the bottom size of the cylinder-shaped spacer may be reduced while ensuring the top size of the cylinder-shaped spacer, that is, it may form a cylinder-shaped spacer having the top size identical to the bottom size and/or an inverse cone-shaped spacer having the bottom size less than the top size, such that the design requirement for the high resolution TFT-LCD can be met.

The mask provided with the Fresnel zone plate according to the embodiment of the present invention, not only may be used to produce the cylinder-shaped spacer and the inverse cone-shaped spacer, but also may be used to produce the spacer with the special shape, so as to meet the design requirement of various specifications of liquid crystal display apparatuses and reduce the period and cost for producing the mask and the spacer.

In an example, as shown in FIG. 1, the Fresnel zone plate 4 has a circular cross section corresponding to the light transmission region 81 on the mask substrate. In particular, a circular zone 41 is provided on a center of the Fresnel zone plate 4 and a plurality of circular ring-shaped bright zones 42 and dark zones 43 arranged on the Fresnel zone plate 4 in sequence in a radially outward direction of the circular zone 41. The bright zones 42 are light transmission zones while the dark zones 43 are light shielding zones. The plurality of circular ring bright zones 42 and dark zones 43 are arranged alternately. Thus, as illustrated in FIG. 2, when (parallel) light (as indicated by straight arrows in FIG. 2) passes through the Fresnel zone plate 4, it may pass the plurality of bright zones 42 and is converged into a bright spot at the main focus point P.

As shown in FIG. 3, infinite secondary focus points such as p1, p2, p3, . . . , pn may also be formed in sequence in a light travel direction, i.e., a direction away from the main focus point P. As an example, the distance between the Fresnel zone plate 4 and the main focus point P is the focus length f; the distance between the main focus point P and the secondary focus point p1 may be f/3; the distance between the secondary focus point p1 and the secondary focus point p2 may be f/5; the distance between the secondary focus point p2 and the secondary focus point p3 may be f/7, and so on. On other words, the respective focus points (the main focus point and the infinite secondary focus points) formed by the Fresnel zone plate 4 become more and more dense along the light travel direction. Thus, various shapes of the spacer may be formed depending on various distances between the photo resist 6 and the mask.

As an example, the Fresnel zone plate 4 may include a negative Fresnel zone plate 4a and a positive Fresnel zone plate 4b. As illustrated in FIG. 1, the circular zone 41 may be a dark zone 43. At that time, the Fresnel zone plate 4 is the negative Fresnel zone plate 4a. As illustrated in FIG. 4, the circular zone 41 may be a bright zone 42. At that time, the Fresnel zone plate 4 is the positive Fresnel zone plate 4b. The positive Fresnel zone plate 4b and the negative Fresnel zone plate 4a may both have function of converging the light.

Further, as shown in FIG. 2, all of the circular zone 41, the bright zones 42 and the dark zones 43 in the Fresnel zone plate 4 form zone orders of the Fresnel zone plate 4 and the circular zone 41 forms the first order, and as shown in FIG. 2, the number of the zone orders of the Fresnel zone plate 4 is 13. In particular, along a radially outward direction, the (dark) circular zone 41 in the negative Fresnel zone plate 4a forms the first order; its adjacent outside bright zone 42 forms the second order; the dark zone 43 adjacent to the second order bright zone 42 forms the third order; the bright zone 42 adjacent to the third order dark zone 43 forms the fourth order, and so on. As shown in FIG. 4, the (bright) circular zone 41 in the positive Fresnel zone plate 4b forms the first order; its adjacent outside dark zone 43 forms the second order; the bright zone 42 adjacent to the second order dark zone 43 forms the third order; the dark zone 43 adjacent to the third order bright zone 42 forms the fourth order, and so on. In practice, in order to ensure the effect of forming the spacer while reducing the difficulty in producing the mask, the number of zone orders of the Fresnel zone plate 4 may be any integer of 3-13, for example, the number of zone orders may be 11. Alternatively, the specific number of zone orders of the Fresnel zone plate 4 in the mask may also be other integers. It is not limited herein.

In order to explain the work process of the mask including the Fresnel zone plate better, the following specific parameters are provided. These parameters may include: a maximum radius R of the Fresnel zone plate 4, that is, the distance between the center point of the Fresnel zone plate 4 and an edge of the Fresnel zone plate 4 is R; a main focus length of the Fresnel zone plate 4 is f, that is, the distance between the center point of the Fresnel zone plate 4 and the main focus point P is f; and a total number of the zone orders of the Fresnel zone plate 4 is m, that is, such as 3, 11 or 13 as described above. In an example, in order to ensure the effects of exposure and development, an incident light irradiated on the Fresnel zone plate 4 may typically be a monochromatic parallel light (as indicated by the straight arrows in FIG. 2) by controlling the incident light with a wavelength of λ (the color of the light depends on its wavelength, for example, a red light has a wavelength of about 600 nm, a green light has a wavelength of about 500 nm, a blue light has a wavelength of about 400 nm). Specifically, the value of the above main focus length f may be obtained from the relation among the radius R, the total number m of the zone orders and the wavelength λ of the incident light. It follows a formula of f=R*R/mλ.

The imaging formula of the Fresnel zone plate is:

$$\frac{1}{ρ} + \frac{1}{{r}_{0}} = \frac{1}{f} ,$$

where ρ is the distance between the light source and the Fresnel zone plate, and the distance indicated by ρ is infinite in case that the incident light is processed parallel light; r₀ is the distance between the center of the Fresnel zone plate and the bright spot at the main focus point P, thus, when ρ is the infinite, r₀ is equal to f, that is, the distance between the center of the Fresnel zone plate and the main focus point P is the main focus length f.

As an example, referring to FIG. 3, when the distance between the mask substrate of the mask and the glass substrate 5 is less than the main focus length f, the parallel light is in a converged stage after passing through the mask and is irradiated on the photo resist 6 to form the inverse cone-shaped spacer 62; when the distance between the mask substrate and the glass substrate 5 is greater than the main focus length f and less than the secondary focus length 4f/3, the parallel light passing through the mask becomes in a dispersed stage after being converged, and thus forms the positive cone-shaped spacer 63; when the distance between the mask substrate and the glass substrate 5 is equal to (or approaches) the main focus length f, the parallel light passing through the mask is just in a critical position between the converged stage and the dispersed stage, and thus forms the cylinder-shaped spacer 61. Therefore, for the mask provided by the embodiment of the present invention, the spacer having different shapes may be formed by controlling the distance between the mask and the glass substrate, that is, it includes the cylinder-shaped spacer 61, the inverse cone-shaped spacer 62 or the positive cone-shaped spacer 63, thereby meeting the requirements of different specification of the TFT-LCD, in particular, the high resolution TFT-LCD.

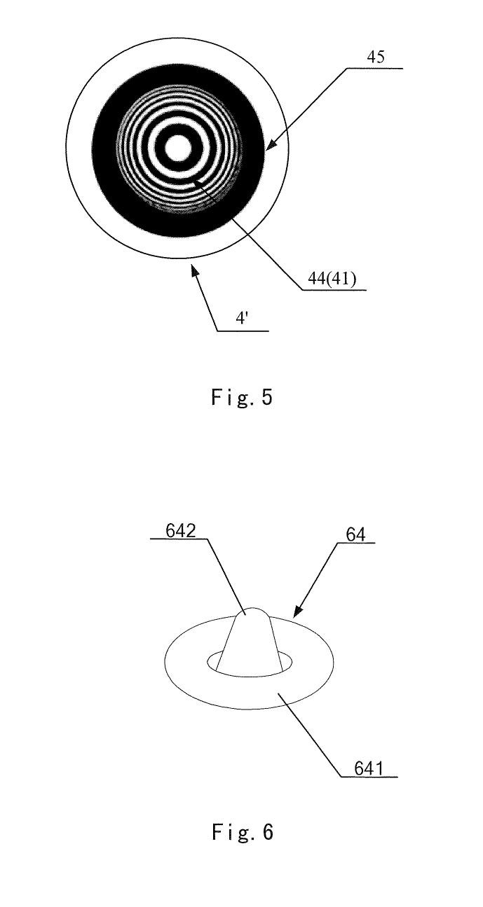

In a specific example, in order that a spacer not only may have a main function of separation, but also may have an auxiliary function of separation, that is, there is a step in one spacer, as illustrated in FIG. 5, the Fresnel zone plate 4 has a circular cross section and is a composite Fresnel zone plate 4′ having an inner zone plate 44 and an outer zone plate 45. The inner zone plate 44 may be located at a center of the outer zone plate 45 to form the circular zone 41 of the composite Fresnel zone plate 4′. In this way, when the distance between the mask substrate 1 of the composite Fresnel zone plate 4′ and the glass substrate 5 is greater than the main focus length f and less than the secondary focus length 4f/3, it may forms a spacer 64 having a special shape with high central part and low peripheral part. As shown in FIG. 6, there is a step between a peripheral circular ring 641 of the above spacer 64 and a central cylinder-shaped protrusion 642, thus, the peripheral circular ring 641 can protect the central cylinder-shaped protrusion 642 effectively. In this way, the spacer 64 not only may have a main function of separation, but also may have an auxiliary function of separation. The spacer 64 having a special shape with high central part and low peripheral part may be called as a combined spacer of a cylinder and a circular ring.

Specifically, the number of zone orders of the inner zone plate 44 of the composite Fresnel zone plate 4′ may be 11 and the number of zone orders of the outer zone plate 45 may be 3. Certainly, the specific numbers of zone orders of the inner zone plate 44 and the outer zone plate 45 may be adjusted on the basis of the desired specific structure of the spacer, and are not limited herein.

The specific production parameters of the mask provided by the embodiment of the present invention may be determined by a formula

ρₖ=\sqrt{kbλ}

where ρₖ is the radius of the k^{th} zone order of the Fresnel zone plate 4, k is an index of the zone order, b is a prescribed distance between the mask and the photo resist 6, λ is a wavelength of the incident light. In this way, the corresponding mask may be produced on the basis of the prescribed distance b between the mask and the photo resist 6, the index k of the zone order and the wavelength λ of the incident light, and meanwhile the main focus length f of the Fresnel zone plate 4 in the mask may be known. In a specific use, the reasonable position of the mask, i.e., a suitable distance between the mask and the photo resist 6, may be determined on the basis of the main focus length f, so as to form the spacers having various structures.

An embodiment of the present invention also provides a spacer produced by using the mask as described in the above embodiment.

As an example, as illustrated in FIGS. 3 and 6, it includes the cylinder-shaped spacer 61, the inverse cone-shaped spacer 62, the positive cone-shaped spacer 63 and the spacer 64 having a special shape with high central part and low peripheral part, which are produced by the mask in accordance with the above embodiment. In this way, the design requirements for high resolution TFT-LCD (or different specifications of the liquid crystal display apparatus) may be satisfied.

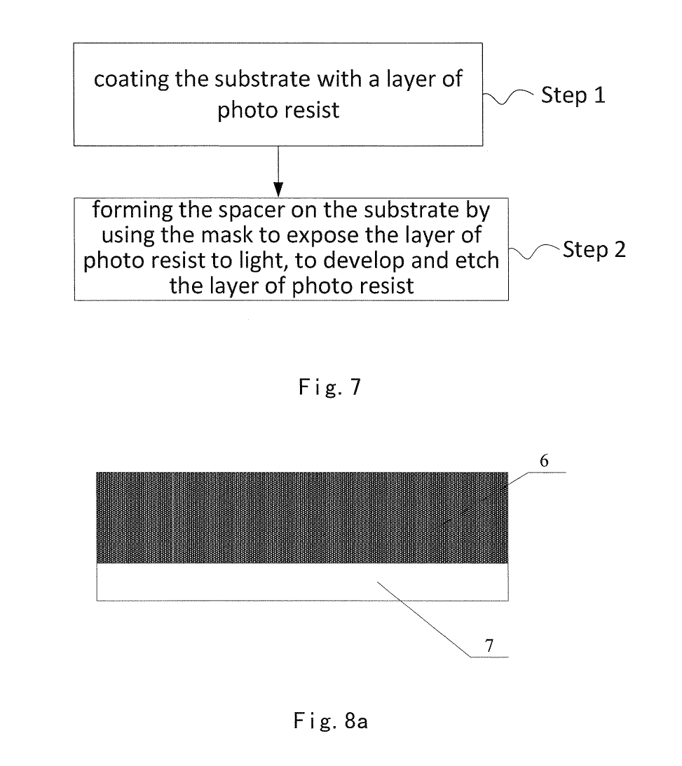

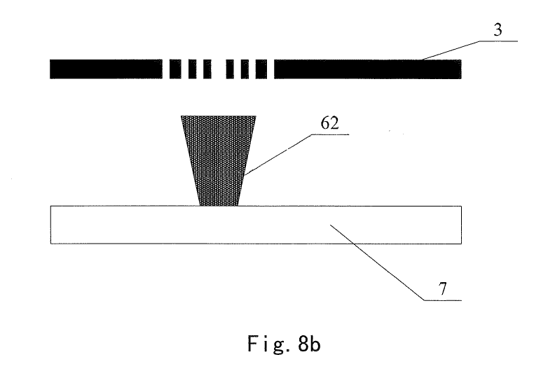

An embodiment of the present invention also provides a method for producing a spacer. As shown in FIGS. 7-8 (FIGS. 8a-8b called collectively as FIG. 8), the method includes:

Step 1 of coating the substrate 5 with a layer 6 of photo resist, in combination with FIG. 8a; and

Step 2 of forming the spacer 61 or 62 or 63 on the substrate 5 by using the mask 3 as described in the above embodiment to exposing the layer of photo resist 6 to light, to develop and etch it in sequence, in combination with FIG. 8b.

It should be noted that the method for producing the spacer according to the embodiment of the present invention has been explained with reference to the example in which the inverse cone-shaped spacer 62 is shown in FIG. 8b. The spacers having other shapes may also be formed as long as the distance between the mask 3 and the layer 6 of photo resist is adjusted.

Although several exemplary embodiments have been shown and described, the present invention is not limited to those and it would be appreciated by those skilled in the art that various changes or modifications may be made in these embodiments without departing from the principles and spirit of the disclosure, the scope of which is defined in the claims and their equivalents.

What is claimed is:

1. A mask, comprising a mask substrate on which a light transmission region and a light shielding region are provided,
wherein a Fresnel zone plate is arranged in the light transmission region and configured to form a spacer on a glass substrate.

2. The mask according to claim 1, wherein the spacer is a cylinder-shaped spacer, an inverse cone-shaped spacer, a positive cone-shaped spacer or a combined spacer of a cylinder and a circular ring.

3. The mask according to claim 1, wherein the Fresnel zone plate has a circular cross section composed of a series of concentric circular ring zones, and
wherein a circular zone is provided on a center of the Fresnel zone plate; a plurality of circular ring-shaped bright zones and dark zones are arranged on the Fresnel zone plate in sequence in a radially outward direction; and the bright zones are light transmission zones while the dark zones are light shielding zones, and
wherein the plurality of bright zones and dark zones are arranged alternately.

4. The mask according to claim 3, wherein the circular zone is a dark zone or a bright zone.

5. The mask according to claim 3, wherein all of the circular zone, the bright zones and the dark zones form zone orders of the Fresnel zone plate and the circular zone forms the first order, and
wherein the number of the zone orders of the Fresnel zone plate is 3 to 13.

6. The mask according to claim 5, wherein the Fresnel zone plate has a radius defined as R, a main focus length defined as f, and a total number of the zone orders defined as m; and
wherein an incident light irradiated on the Fresnel zone plate is a monochromatic parallel light with a wavelength of λ; and
wherein the value of the main focus length f is obtained from a formula of f=R*R/mλ.

7. The mask according to claim 6, wherein the mask is used to form an inverse cone-shaped spacer on the glass substrate when the distance between the mask and the glass substrate is less than the main focus length f;
the mask is used to form a cylinder-shaped spacer on the glass substrate when the distance between the mask and the glass substrate is equal to the main focus length f;
the mask is used to form a positive cone-shaped spacer on the glass substrate when the distance between the mask and the glass substrate is greater than the main focus length f.

8. The mask according to claim 4, wherein all of the circular zone, the bright zones and the dark zones form zone orders of the Fresnel zone plate and the circular zone forms the first order, and
wherein the number of the zone orders of the Fresnel zone plate is 3 to 13.

9. The mask according to claim 8, wherein the Fresnel zone plate has a radius defined as R, a main focus length defined as f, and a total number of the zone orders defined as m; and
wherein an incident light irradiated on the Fresnel zone plate is a monochromatic parallel light with a wavelength of λ; and
wherein the value of the main focus length f is obtained from a formula of f=R*R/mλ.

10. The mask according to claim 9, wherein the mask is used to form an inverse cone-shaped spacer on the glass substrate when the distance between the mask and the glass substrate is less than the main focus length f;
the mask is used to form a cylinder-shaped spacer on the glass substrate when the distance between the mask and the glass substrate is equal to the main focus length f;
the mask is used to form a positive cone-shaped spacer on the glass substrate when the distance between the mask and the glass substrate is greater than the main focus length f.

11. The mask according to claim 1, wherein the Fresnel zone plate has a circular cross section and is a composite Fresnel zone plate having an inner zone plate and an outer zone plate, the inner zone plate being located at a center of the outer zone plate to form the circular zone of the outer zone plate.

12. The mask according to claim 11, wherein the number of zone orders of the inner zone plate is 11 and the number of zone orders of the outer zone plate is 3.

13. A spacer produced by using a mask, the mask comprising a mask substrate on which a light transmission region and a light shielding region are provided,
wherein a Fresnel zone plate is arranged in the light transmission region and configured to form a spacer on a glass substrate.

14. A method for producing a spacer using a mask, the mask comprising a mask substrate on which a light transmission region and a light shielding region are provided, wherein a Fresnel zone plate is arranged in the light transmission region and configured to form a spacer on a glass substrate, the method comprising:
coating the substrate with a layer of photo resist; and
forming the spacer on the substrate by using the mask to expose the layer of photo resist to light, to develop and etch the layer of photo resist.

15. The method according to claim 14, wherein the spacer is a cylinder-shaped spacer, an inverse cone-shaped spacer, a positive cone-shaped spacer or a combined spacer of a cylinder and a circular ring.

16. The method according to claim 14, wherein the Fresnel zone plate has a circular cross section composed of a series of concentric circular ring zones, and
wherein a circular zone is provided on a center of the Fresnel zone plate; a plurality of circular ring-shaped bright zones and dark zones are arranged on the Fresnel zone plate in sequence in a radially outward direction; and the bright zones are light transmission zones while the dark zones are light shielding zones, and
wherein the plurality of bright zones and dark zones are arranged alternately.

17. The method according to claim 16, wherein the circular zone is a dark zone or a bright zone.

18. The method according to claim 16, wherein all of the circular zone, the bright zones and the dark zones form zone orders of the Fresnel zone plate and the circular zone forms the first order, and
wherein the number of the zone orders of the Fresnel zone plate is 3 to 13.

19. The method according to claim 18, wherein the Fresnel zone plate has a radius defined as R, a main focus length defined as f, and a total number of the zone orders defined as m; and
wherein an incident light irradiated on the Fresnel zone plate is a monochromatic parallel light with a wavelength of λ; and
wherein the value of the main focus length f is obtained from a formula of R*R/mλ.

20. The method according to claim 19, wherein the mask is used to form an inverse cone-shaped spacer on the glass substrate when the distance between the mask and the glass substrate is less than the main focus length f;
the mask is used to form a cylinder-shaped spacer on the glass substrate when the distance between the mask and the glass substrate is equal to the main focus length f;
the mask is used to form a positive cone-shaped spacer on the glass substrate when the distance between the mask and the glass substrate is greater than the main focus length f.
